(19) United States
(12) Patent Application Publication
(10) Pub. No.: US 2010/0303673 A1
(43) Pub. Date: Dec. 2, 2010

(54) Solar energy powered molecular engine

(76) Inventors: Franklin Dun-jen Hwang, Glendora, CA (US); Ching Ching Huang, Glendora, CA (US); Jennifer Peng, Huntington Beach, CA (US); Francis N. Hwang, Glendora, CA (US); Francine N. Hwang, Glendora, CA (US)

Correspondence Address: FRANKLIN D. KWANG, 949 E. Plymouth Street, Glendora, CA, 91740, US

(21) Appl. No.: 12/583,031

(22) Filed: Aug. 12, 2009

Related U.S. Application Data
(60) Provisional application No. 61/217,089, filed on May 26, 2009.

(51) Int. Cl. B01D 53/02; G03F 7/00; C23F 1/00; B29C 45/00; B32B 3/10; F03G 7/00; B23K 26/38; F02K 9/00

(52) U.S. Cl. 422/120; 430/322; 216/83; 264/219; 216/52; 96/108; 96/243; 428/131; 60/721; 219/121.71; 60/200.1

(57) ABSTRACT

The sun imparts 174 petawatt per second on the earth, and a large portion of this energy is absorbed by the earth's atmosphere in the form of translational energy for the gaseous molecules, i.e. continuous random motion in the average speed range of 500 meters per second on earth's surface. This invention utilizes a partition with large number of through-holes which all have the characteristic of providing greater cross section for gas molecules to transit from one side to the other than the reverse, thus creating a higher statistical probability for the molecules to move from one side of the partition to the other side. By stacking a number of such partitions to emphasize the direction of movement probability of the gas molecules within a container having two open ends, the number of gas molecules at the end of the stack will be more numerous than at the head, thus a pressure differential is established, and this pressure difference is used to push against the stacks of the partition to provide thrust on the container or to drive a turbine to generate electricity or to perform works.

### RELATED APPLICATIONS

This utility application claims the benefit of U.S. Provisional Patent Application No. 61/217.089 filed on May 26, 2009.

### FIELD OF THE INVENTION

This invention utilizes the abundant solar energy received by the planet earth, in the form of translational motion of atmospheric molecules, and creates a pressure differential between the two ends of a stack of specially designed permeable partitions to perform meaningful work.

### BACKGROUND OF THE INVENTION

Earth continuously receives 174 petawatts (1.74×10¹⁵ watts) per second of incoming solar radiation (insolation) at the upper atmosphere. Not all the 174 petawatts arrive at the earth's surface, 6 percent of the insolation (10 petawatts) is reflected back to space, 16 percent is absorbed (28 petawatts), average atmospheric conditions (clouds, dust, pollutants) further reduce insolation traveling through the atmosphere by 20 percent (35 petawatts) due to reflection and 3 percent via absorption (5 petawatts). Therefore, every second there are 96 petawatts of solar energy reaching the earth's surface. The result is an approximate 3,850 zettajoules (ZJ), i.e. 3.85×10²¹ joules, of solar energy per year hitting the surface with land mass receiving 1,000 ZJ. The total energy consumption for the entire world during 2004 was 0.471 ZJ. It is obvious human society can really prosper without the detriments derived from the usage of fossil fuel, if they can utilize this abundance of solar energy.

Photovoltaic conversion of solar energy and direct conversion of sun light into thermal energy are the two most common means employed to derive energy from the sun. However, both methods depend on sunlight to generate power and, therefore, can not produce energy or electricity half of the time. Areas with cloudy/rainy weather greatly reduce the viability (as well as increasing the costs) of either method to produce energy as an alternative to the fossil fuel.

The present invention is based on two facts: (1) more than 1,300 ZJ per year is absorbed by the earth's atmosphere, (2) the absorbed energy powers the motion of atmospheric molecules regardless of whether there is sunlight or not. This invention creates a statistically higher probability in a specific direction of flow for the continuous moving atmospheric molecules by providing a larger cross section for molecules to pass through a stack of partitions having funnel shaped through-holes than the reverse direction of movement. As a consequence, a pressure differential is created between the two ends of this stack of partitions. With this pressure difference, various thrust devices, turbines and compressors can be driven to produce propulsion, electricity, refrigeration and numerous other work applications.

Thorough search of prior arts in patents, patent applications and literatures, indicates that power generation by solar means can be categorized as converting solar radiation into electricity directly (photovoltaic approach) or into heat to move a fluid (liquid or gas) at high speeds to rotate a turbine to produce electricity. None of those prior arts incorporates the basic concept of our invention. Only two prior patents (6,167,704 on Jan. 2, 2001 and 6,962,052 on Nov. 8, 2005, both by Goldenblum) have been found utilizing particle movement as an energy source. Goldenblum has claimed the usage of unidirectional stoppers, unidirectional gates (molecular size) and unidirectional elements to selectively block particles (in gas and liquid) with kinetic energy traveling in a direction opposite to a specified one. Special emphasis of these two patents was placed on constructed molecular gates and stoppers to actively reject and stop movement of particles from one direction vs. the opposite; while our invention simply utilizes the physical configurations of a series of bidirectional through-holes on partitions to provide a difference in translational cross sections for gas molecule movement, and through this difference to achieve a preferred direction of gas flow. In our invention, there is no selective blocking or using any other form of external energy to block the movement of certain molecules or open and shut molecular gates (as claimed in Goldenblum's patents). Furthermore, the system specified by Goldenblum is a closed one with its fluid separated from any external fluid while obtaining energy through heat exchanges. Our invention only applies to an open atmospheric system.

Our invention complies fully to the laws of thermodynamics as well as fundamental physics by utilizing immovable through-holes to provide a transition cross sectional difference to the atmospheric molecules passing through a partition. No external energy is required to open or close the through-holes. Although Goldenblum claims deriving energy solely from the environment for his systems, it may not hold true. For example, his unidirectional gates will open and close to provide selective blocking of particles traveling through these gates to produce an imbalance in direction of particle flow or pressure. Under the conditions of standard temperature (0° C.) and pressure (1 atm), known as STP, there are 3.3×10¹⁸ collisions per mm² per second by atmospheric molecules with its containing walls. Assuming his molecular gate has an area of 10 square nanometer (i.e. 1 nm=1×10⁻⁶ mm, thus 10 nm²=1×10⁻¹¹ mm²), then his gates must open and close at a minimum frequency higher than 3.3×10⁷ times per second (33 MHz) to achieve any selective blocking. Opening and closing a molecular gate at this frequency and at the gate speed exceeding 500 m/sec will require substantial external energy input exceeding that provided just from the environment. Goldenblum also claims that randomly moving charged particles in a static or flowing fluid under a magnetic field will separate radially into + (positive) and − (negative) streams and through muzzles of an inner membrane, one of the streams will be able to rotate a shaft. However, he does not account the fact that + and − particles move in all random directions due to Brownian motion within a static or flowing fluid, and each will simply move radially under the same magnetic field still maintaining total randomness unless he can first make all the charged particles moving in one or two uniformed directions (for + or − particles). By doing so his process becomes electrolysis or electroplating, which requires much more external energy input into the system. Consequently, all the movement of + and − particles will cancel each other out in such a static or flowing liquid and thus no usable imbalanced vectorial force is produced to do any work.

### SUMMARY OF THE INVENTION

This invention utilizes a partition with a large number of through-holes which all have the characteristic of having greater cross section for gas molecules to transit from one direction than the reverse, thus creating a higher statistical probability for the molecules to move from one side of the partition to the other side than the reverse. By stacking a number of such partitions within a container having two open ends, the number of gas molecules that tend to move toward and congregate at the end of the stack will be higher than those doing the reverse, thus a pressure differential is established between the head of the stack vs. the end, and this pressure difference is used to push against the stacks of the partition to provide thrust on the container or to drive a turbine to generate electricity to achieve work.

### BRIEF DESCRIPTION OF THE DRAWINGS

FIG. 1 illustrates the basic concept of this invention in a very simple two-dimensional rectangular box. Within it, a partition with a single funnel shaped through-hole (i.e. hole has large opening diameter on top and tapers down to a stem with much smaller end hole as shown) divides the box into two halves A and B. When a ball with its diameter smaller than the diameter of the end hole undergoes continuous movement at a fixed velocity and perfect elastic collisions with the walls, it will spend more time in the B half having the smaller end hole of the funnel stem. This is due to the fact that the larger cone opening provides a greater cross section for the ball to bounce through the bottom end hole than when the ball transits from the opposite direction.

FIG. 2 alters the configuration of FIG. 1 by adding more funnel shaped holes on the partition. This will enhance the dwell time of the ball on the half having the side of smaller end holes of the funnel stems. FIG. 3 further modifies the configuration of FIG. 2 with additional partitions with multiple funnel shaped through-holes as well as more balls introduced. A software written to simulate this configuration based on simple rules of (1) perfect elastic collisions between balls and between balls with the walls, i.e. angle of incidence is equal to angle of exit; (2) conservation of momentum; (3) the range of diameters of funnel top and stem end-hole openings are multiple times of the diameter of the ball; (4) the balls travel at a speed ranging from several multiples of the dimension of the rectangular box to several hundred times per second. This software demonstrates that after a period of time of allowing the balls to move around, there will be a gradient established in terms of the number of balls in each compartment defined by partitions as illustrated in FIG. 4. For example, the bottom compartment in FIG. 4 has the most balls, and the compartment above it has less and so on with the compartment just beneath the top one having the least number of balls (the top compartment, i.e. head of the stack, has slightly more than the compartment immediately beneath it due to the fact that there are only one set of through-holes to exit instead of two exit channels for each compartment beneath it). By substituting the balls with atmospheric molecules (oxygen and nitrogen) and opening up both ends of the box, FIG. 4 becomes a gas compressor, in which 1 atmospheric air molecules are being compressed to higher than 1 atmospheric pressure.

FIG. 5 presents a photograph showing an actual 1-micron diameter taper hole drilled by pulsed diode pumped UV laser on a stainless steel substrate. These dimensions of holes can be routinely drilled by pulsed diode pumped lasers on a variety of materials for pin-hole cameras or liquid orifice applications. Furthermore, by adjusting the laser pulse width and repetition rate, one can achieve a hole having various taper angles to virtually no taper (i.e. straight wall).

A potential fabrication process for our invention, the molecular engine, is illustrated by FIGS. 6, 7, 8A and 8B. The initial step shown in FIG. 6 is to have large number of tapered holes drilled on a substrate by multiple high repetition rate diode pumped pulsed UV lasers through a two-step procedure (only one laser is shown for clarity), which first achieves a straight through-hole to form the stem then a different pulse rate and width to achieve the top taper portion at a specified incline angle. The substrate is rotated at a speed matching the hole drilling rate of the lasers while the lasers are individually moved on separate slides to drill a densely packed spiral pattern of through-holes on to the substrate.

The second step as shown in FIG. 7 is to conduct vapor deposition (such as Chemical Vapor Deposition, Plasma Enhanced Chemical Vapor Deposition, Sputtering Deposition or electric discharge formation of nanolayers) in a vacuum chamber to achieve uniformed deposition of another material on to the substrate to reduce each hole diameter to a desired dimension, such as 0.05 micron or less for the stem portion (shown in the before and after inserts of FIG. 7). The third step contains two sub-steps as illustrated in FIG. 8A and 8B dicing the large substrate with coated through-holes into multiple partitions of specified dimensions to fit into containers of various sizes and shapes along with assembling the container with an air intake controller to form a solar energy powered molecular engine.

FIG. 9 illustrates a mechanical device to control the aperture opening to regulate the amount of air entering into the space above the head of the stack of partitions, thus controlling the amount of pressure difference that can be produced by this molecular engine.

FIG. 10 shows how this invention can be used as a thrust device to levitate and propel a vehicle along with its usage in steering and braking the vehicle.

FIG. 11 presents how this thrust device can be combined with burning of liquid fuel to increase thrust for aviation and military applications.

FIG. 12 illustrates a vertical take-off and landing aircraft using the molecular engine for levitation while using fuel powered jet engines for propulsion.

FIG. 13 provides the concept drawing of a mobile home that can levitate and be moved based on the invention.

FIG. 14 illustrates how this molecular engine can be used to generate AC (or DC) electricity.

FIG. 15 shows how this molecular engine can be used as a crane to lift weight or as an elevator to move people or objects.

### DETAILED DESCRIPTION OF THE INVENTION

The basic concept of this invention can best be described by the following sequential scenarios:

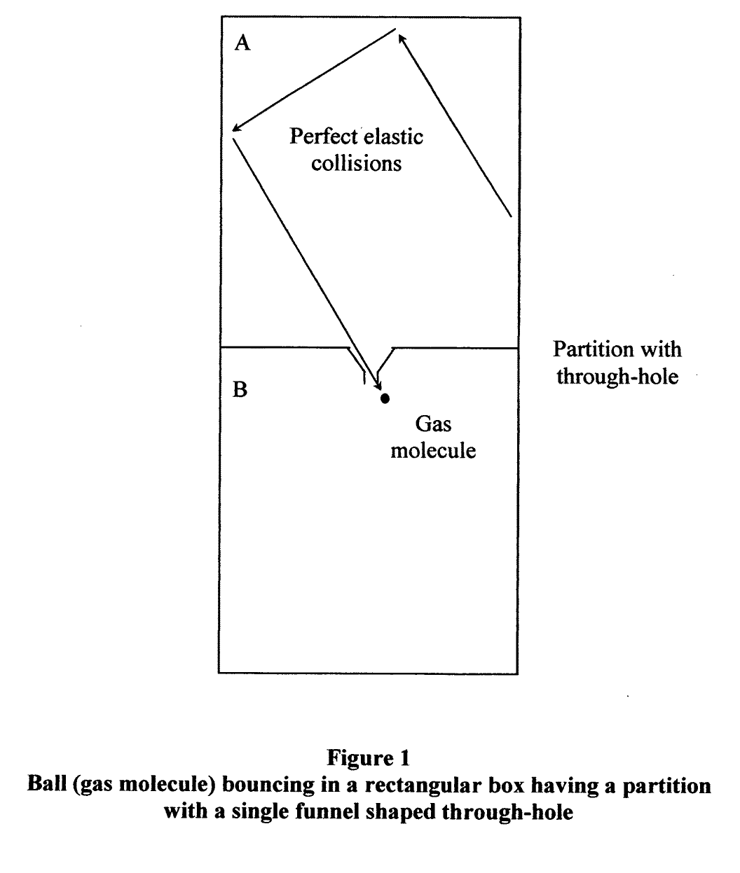

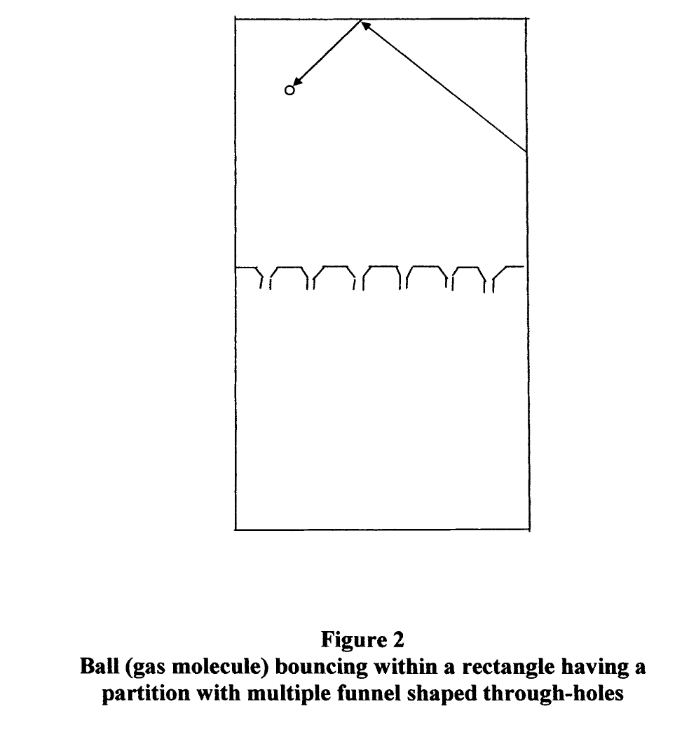

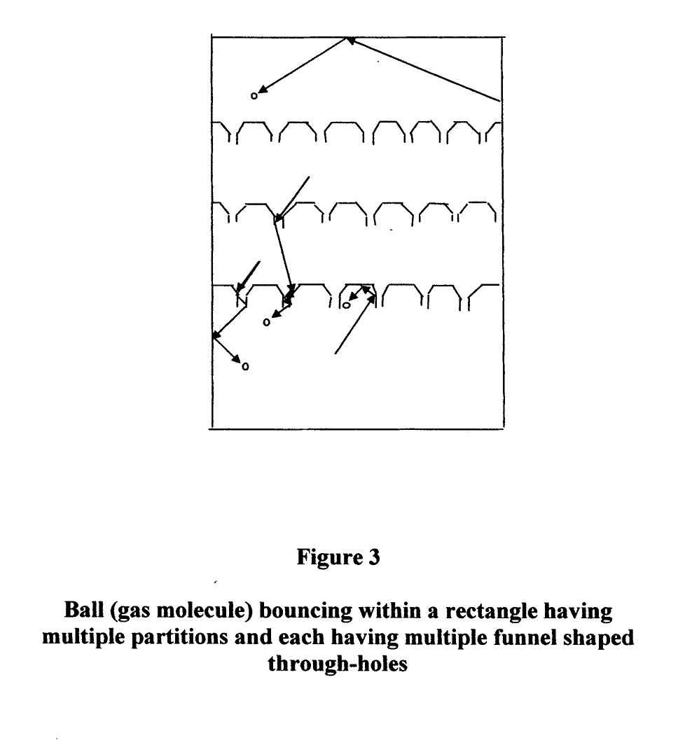

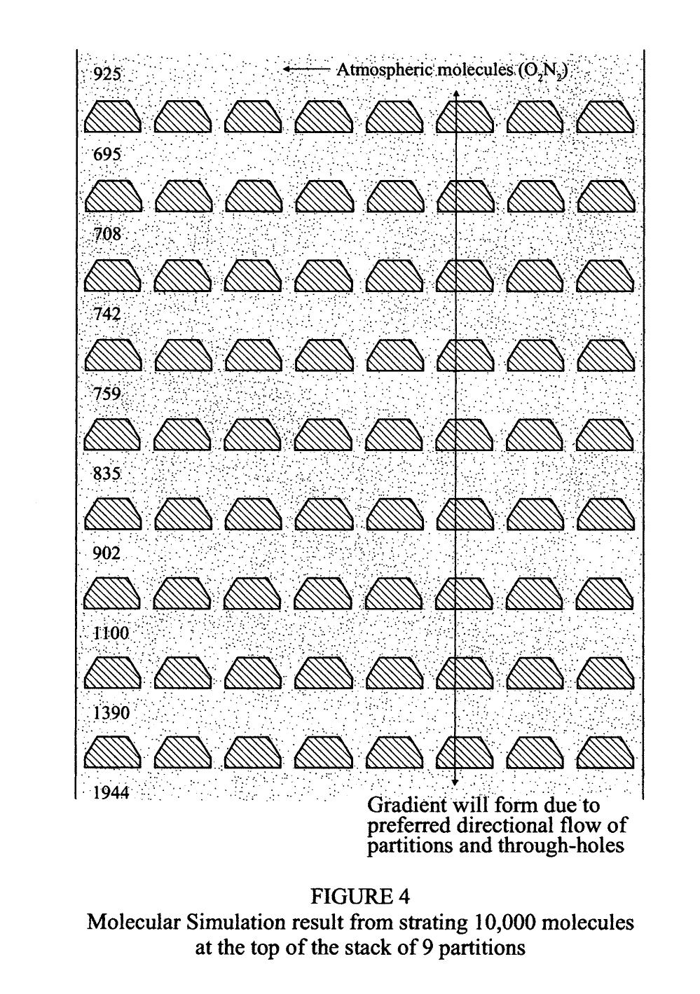

1. In a 2-dimensional rectangle, a partition is inserted in the middle to separate the rectangle into two equal halves. A straight through-hole is added to this partition to allow any perfectly elastic bouncing ball to pass through. When a ball with a finite velocity and with a diameter smaller than the hole is injected into this rectangle, it will bounce from one half to another through the hole. After a sufficient time period, one will find the ball will spend equal time on the two halves of the rectangle.
2. Instead of a 2- dimensional rectangle, a 3-dimensional rectangular box is replacing the rectangle. A partition of certain thickness with a right size of round through-hole having straight side (non-tapered) wall is inserted into the middle of this sealed box and a single perfectly elastic ball is injected into the box with a fixed velocity. In an ideal situation, the ball will be colliding with the walls while maintaining its momentum and speed. After a finite time period, the ball will pass through the hole in the partition numerous times and spend equal time on the two halves of the box.
3. Altering the second scenario by changing the round and straight through-hole with a hole shaped like a funnel with the smaller opening of the stem end just larger than the diameter of the ball, then the ball is likely to spend more time on the half with the smaller opening than the side with the large cone shaped opening. The reason is the ball will have a larger cross section (higher probability) to have the correct incidence angles to enter into the cone from the side with larger cone opening and exit the partition to the other half than from the smaller diameter end of the funnel stem. This scenario is illustrated in FIG. 1.
4. Now, let us introduce more elastic balls into the box. For the second situation (with round non-tapered through-hole), the balls will spend equal time on the two halves. In other words, at any give time, there are likely equal number of balls in the two halves. However, for the third scenario (with funnel shaped through-hole), one will find that the balls will spend more time on the side with smaller diameter opening of the through-hole. Consequently, at any give time, one will find more balls on the side with smaller diameter opening. However, in this closed system, the more balls accumulated in the half with the smaller diameter opening of the through-hole, will eventually increase the amount of balls going the other way to reach an equilibrium with one half having more balls than the other, i.e. the difference in number of balls in the two halves is in inverse ratio (bottom half B has more than the top half A per FIG. 1) to the transit cross section difference.
5. Instead of balls, let us consider the atmospheric molecules (nitrogen and oxygen). Those molecules will be colliding with each other and with the walls of the box constantly due to the thermal energy impinged on earth by the sun. At the temperature range on earth (sea level to a couple of thousand feet of altitude), the gas molecules have a speed of around 500 meters per second and behave very much like perfectly elastic balls when colliding with each other and with most solid surfaces, such as smooth container walls. The higher the temperature, the more translational energy (thus higher speed) the molecules will move, and the more they will behave like perfectly elastic balls bouncing around. With the diameter of the funnel shaped hole opening equaling to a few times of the mean free-path length (distance traveled by a molecule before encountering a collision with either another molecule or a wall surface), the more molecules will be aggregated at the half of the box with the smaller through-hole opening. Since more bouncing molecules means higher collisional force exerted on the partition and the surrounding walls, a pressure differential results between the two halves.
6. Instead of just one opening, let us have millions of such funnel shaped through-holes on the partition of the box as illustrated by FIG. 2. At any given time, more molecules will be bouncing around in the half of the box with the smaller through-hole opening than the other half, thus a pressure differential is created.
7. Instead of just one partition with millions of funnel shaped through-holes, we will have multiple partitions within a closed ended box as shown in FIG. 3. We, then, will have a continuous pressure gradient building up with each partition experiencing a pressure difference between its two sides. For an open ended box, the molecules will flow in from the head of the stack and move through the partitions continuously. At each and the final partition, the partition only experiences a small pressure difference between its two sides, although the cumulative pressure difference between the first the final partitions will be large. With the box open on both ends, this partitioned box creates a pressure difference between 1 atmosphere at one end and larger than 1 atmosphere pressure on the other end, i.e. an atmospheric gas compressor is thus formed.
8. This large pressure difference will force the box to move toward the 1 atmosphere pressure end or the high pressure end can be exhausted to turn a turbine. Therefore, a thrust device is created or an electricity generator can be built with it or by allowing the compressed gas to expand rapidly to effect cooling and forms the refrigeration unit.

In FIG. 4, results of injecting 10,000 gas molecules into a closed rectangular box with 9 partitions having funnel-shaped through-holes in the partitions are illustrated. The diameter of a through-hole and its inclining wall angle will have an effect on the transit cross sections from opposite sides of the hole, thus influencing the efficiency of creating a pressure differential and the magnitude of such pressure difference. Furthermore, considerations must be given to the space between partitions and various methods of controlling air intake into the system as well as providing laminar air flow into the system to increase its efficiency.

Here an example is presented to illustrate the difference in gas pressure this solar energy powered molecular engine can generate. It does not limit the invention to only this efficiency.
1. By utilizing the basic physics law that the angle of incidence is equal to angle of exit in an elastic collision with no loss of momentum and the “ray” tracing method (shooting numerous balls, i.e. gas molecules, at the funnel shaped through-holes at different incidence angles to the openings, top and bottom), the analysis indicates that the funnel shaped through-hole can readily provide greater than 10% difference in cross sections of transiting the funnel shaped through-hole due to the larger area of the top opening and the inclining side to direct the balls through the smaller opening of the stem. In other words, the gas molecules has at least 10% higher probability of transit from the top end (larger opening) of a funnel shaped through-hole than those traveling from the bottom stem end of the through-hole toward the top end.
2. Ideal gas law states that Avogadro's number 6.022×10²³ molecules exist in 22.4 m³ of volume under Standard Temperature and Pressure condition (0° C., 1 atm pressure—STP). Since each molecule undergoes 0.5×10¹⁰ collisions per second (average velocity of a molecule under STP conditions is 500 m/s, which divided by mean-free path of a molecule before collision, 60×10⁻⁹ m, gives how many collisions a molecule will encounter per second), so there will be 3×10³³ collisions within the 22.4 m³ volume per second.

By using the formula for ideal gas,
the number of collisions against a wall=¼(N/V)×vₐᵥₑ
where N=Avogadro number, V=22.4 m³, and vₐᵥₑ=500 m/s (average velocity of molecules).

Therefore, Number of collision against a wall=3.3×10²⁴ per m² per second or 3.3×10¹⁸ per mm² per second under STP conditions. This number of collisions represents one atmospheric pressure which equals to 14.6956 pounds per square inch.

3. With a partition having dimensions of 10 mm by 10 mm and having 100 through-holes (each hole's top opening area is 0.01 mm in diameter) per mm, the 100 mm² partition will have 1,000,000 holes (10,000 holes/mm²×100 mm²) with the total top hole opening area equaling to 78.5 mm² [i.e. with each top opening of a hole diameter being 0.01 mm, then each hole top area=π×radius²=π×(5×10⁻³ mm)²=7.85×10⁻⁵ mm². With 1×10⁶ holes, the total hole area=7.85×10⁻⁵×10⁶=78.5 mm²].

Consequently, there are 3.3×10¹⁸×78.5=2.6×10²⁰ molecules hitting the top areas of all the through-holes on this partition per second.

4. Therefore, there will be 6.022×10²³+(2.6×10²⁰×10%)=6.02226×10²³ molecules residing on the side of the first partition having the bottom ends of the through-holes after just one second of time in gas molecule movement, i.e. a 0.004% pressure difference results.
5. To increase the difference, one can increase the area of the partition. For a 100 mm×100 mm area (total 10,000 mm² which is equal to an area of 15.4 square inch), the gas molecules on the side with smaller stem opening of the partition will be 6.022×10²³+(3.3×10¹⁸×7,850)=6.282×10²³. Now, we have a 4.3% difference after one layer of partition.
6. With a stack of 17 partitions, one can obtain a pressure difference between 1.00 atm and 2.04 atm (i.e. P_{bottom}=P_{head}×1.043¹⁷).
7. The partition thickness can be set at 0.6 mm (0.025 inch) and the space between partitions is set at 2.5 mm (0.1 inch), therefore the entire 17-partition stack can have a height of less than 30 mm (2.1 inches). The total dimension of an open-ended container can be around 30 mm (H)×100 mm (L)×100 mm (W) and having a thrust capability of 227 pounds (i.e. 1 atm×14.6956 pound per square inch/atm×15.4 inch²).

The conclusion is that an engine with dimensions of 2.1 inches (H)×4 inches (W)×4 inches (L) with an estimated weight of 2 lbs which can deliver a thrust of 227 lbs is thus created by purely using atmospheric molecules driven by absorbed solar energy regardless of day, night or weather conditions. By adding an air intake volume regulating device, such as a mechanical accordion type of cover plate shown in FIG. 9, one can regulate the amount of air delivered to the head of the stack and subsequently regulates the amount of thrust can be delivered by this engine to perform work.

The critical step in manufacturing this type of molecular engine is the fabrication of the partition with funnel shaped or other types of through-holes that provides a higher statistical probability for atmospheric molecules to transit from one direction vs. the reverse. Here, a specific example as covered in one of the embodiments is given on the fabrication method of a stainless steel partition with rows of funnel shaped through-holes along with subsequent assembling procedure to make the molecular engine described in the previous paragraph. Other manufacturing methods are presented in the Claim section to fit the type of through-holes used.

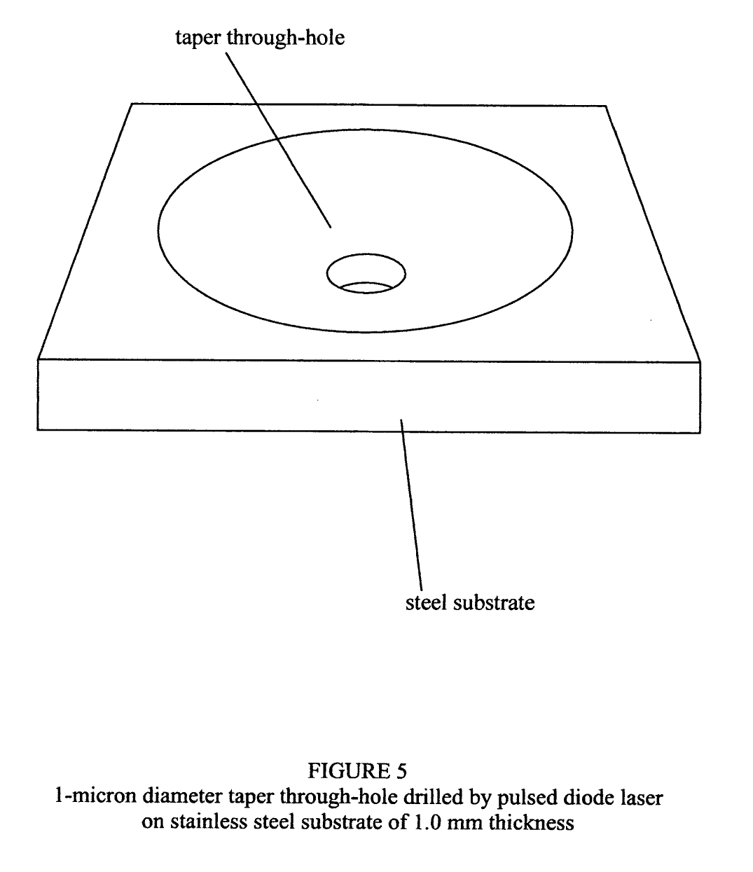

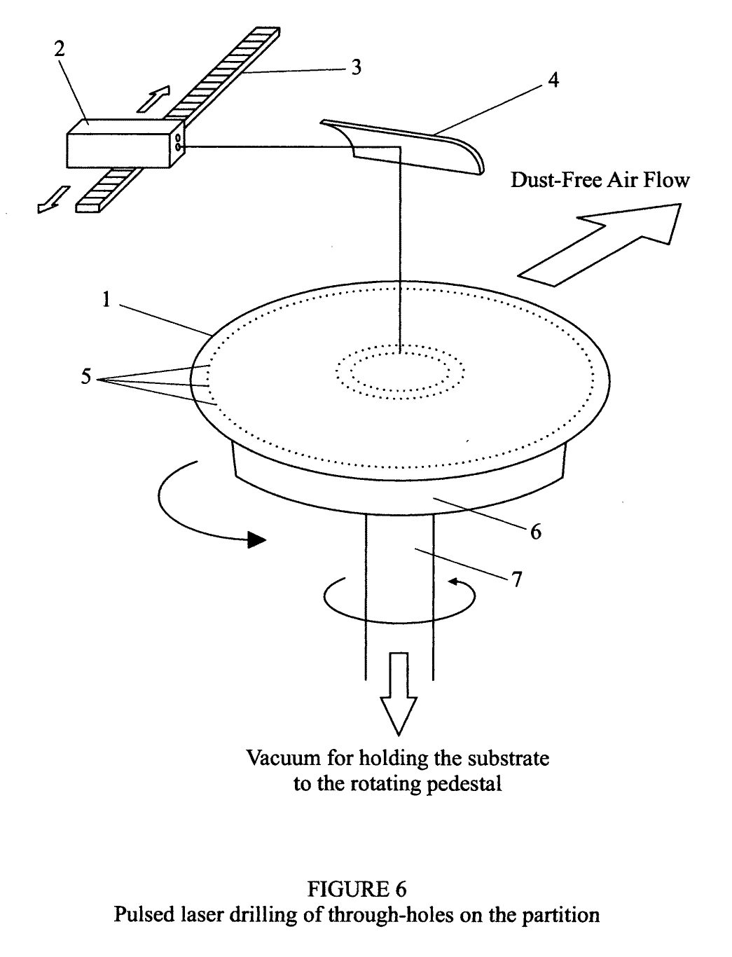

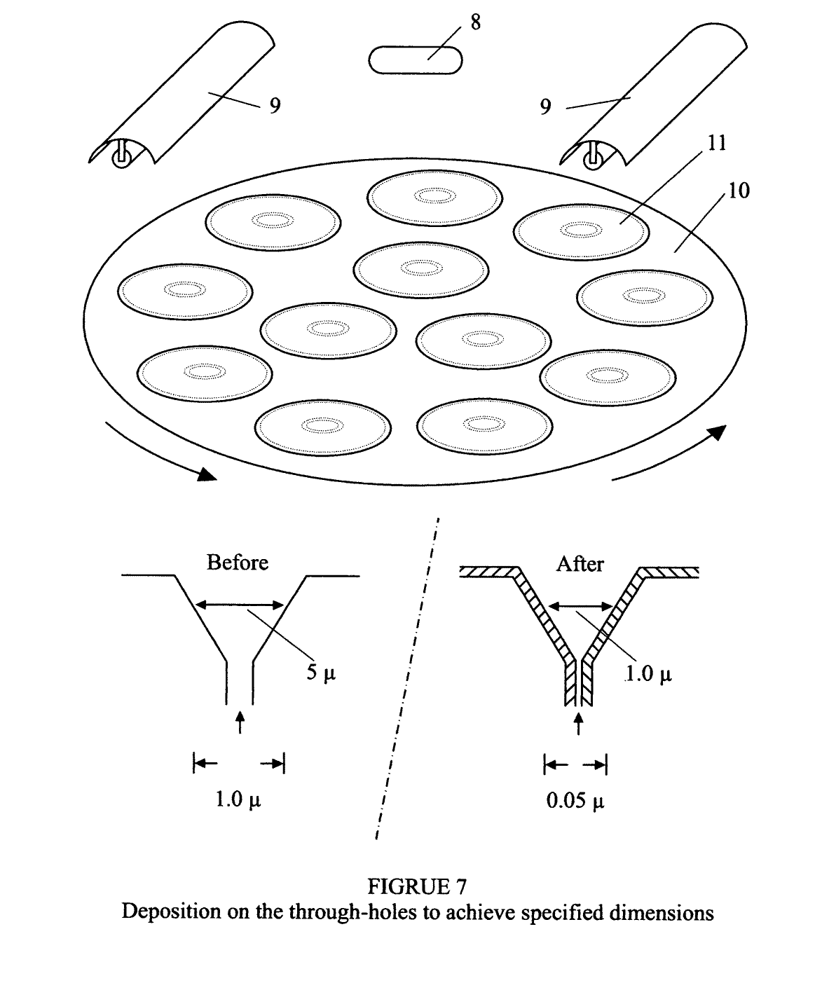

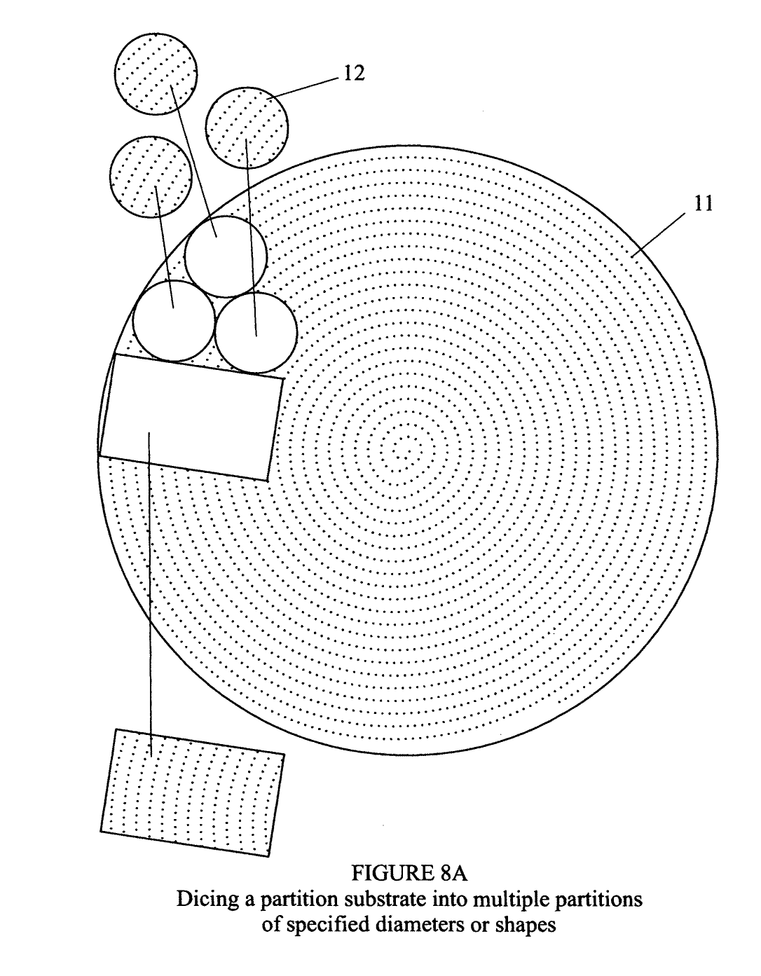

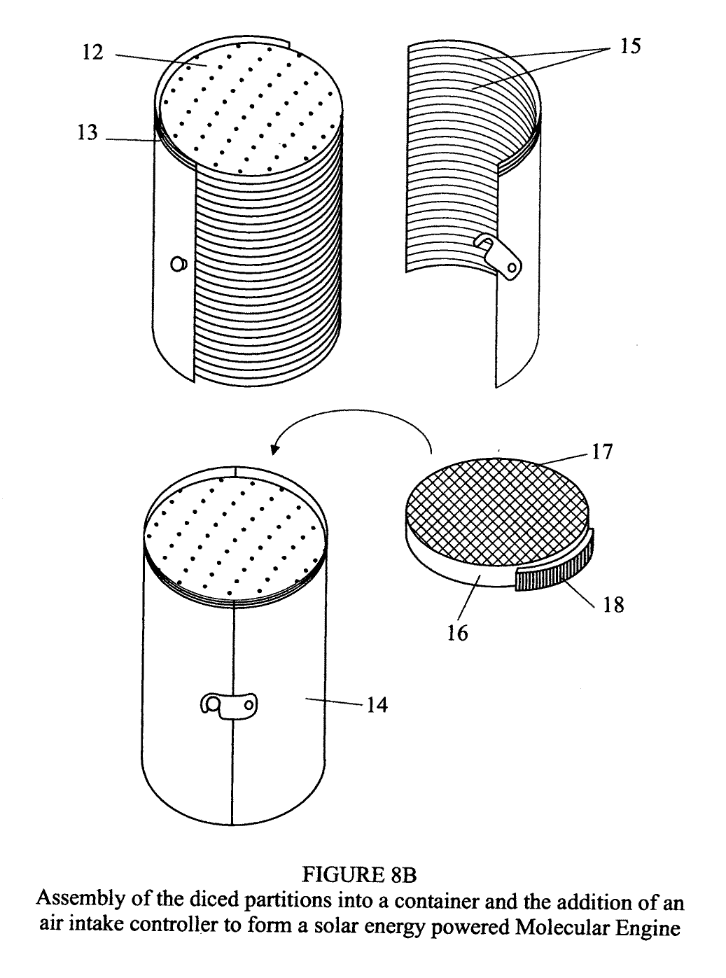

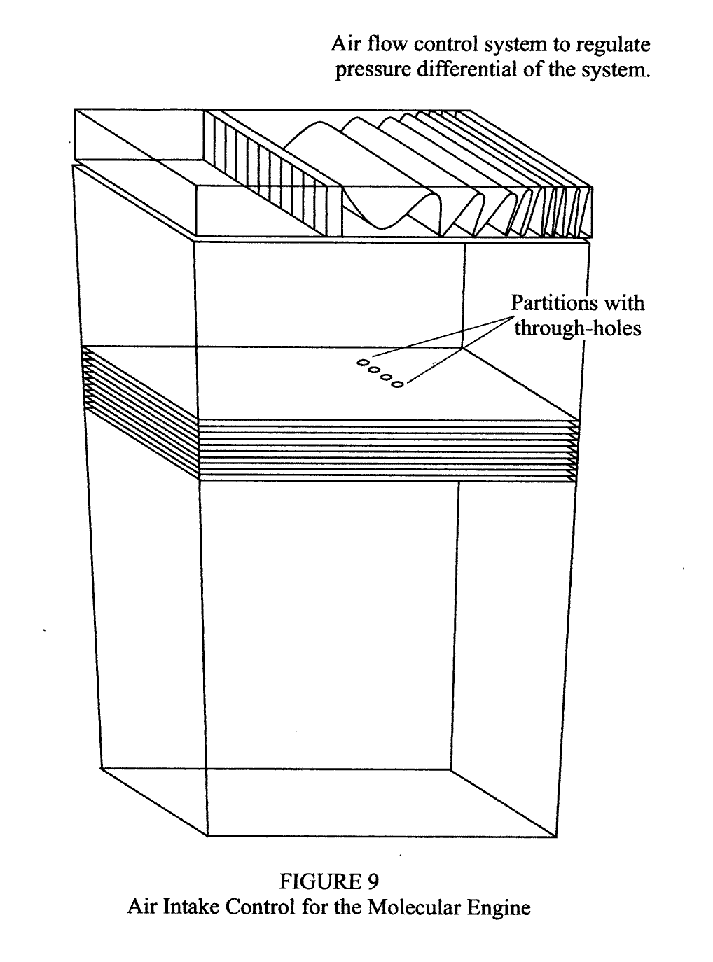

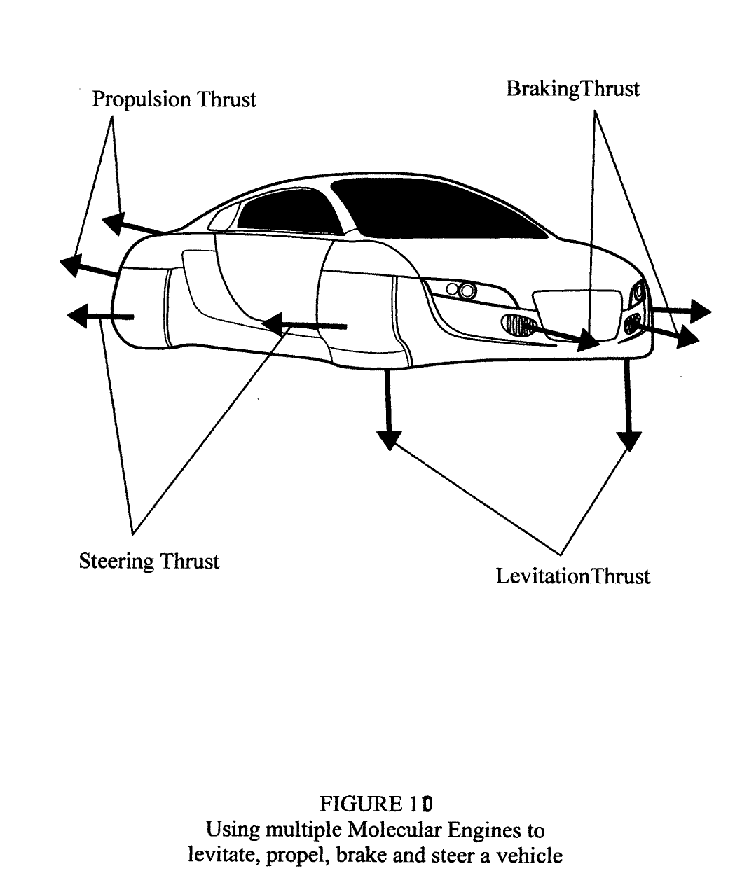

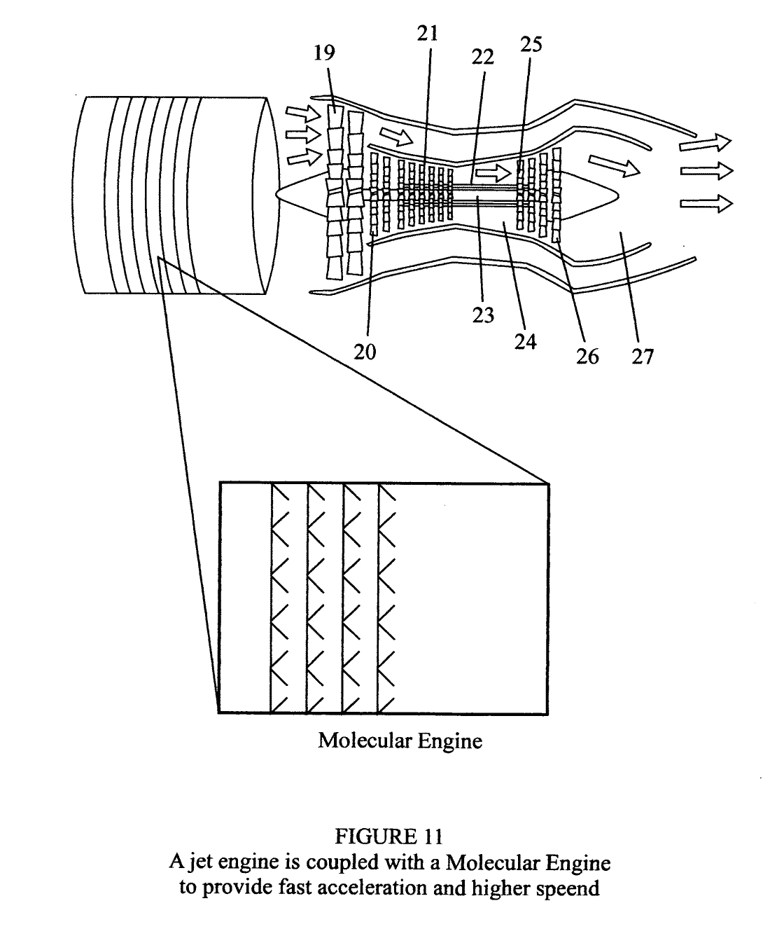

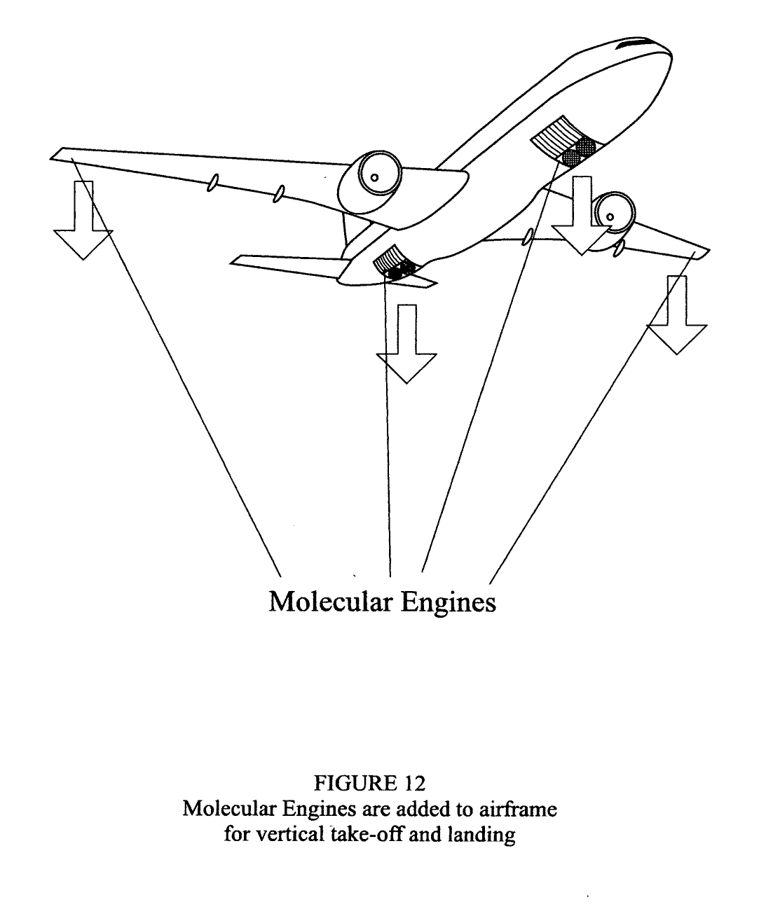

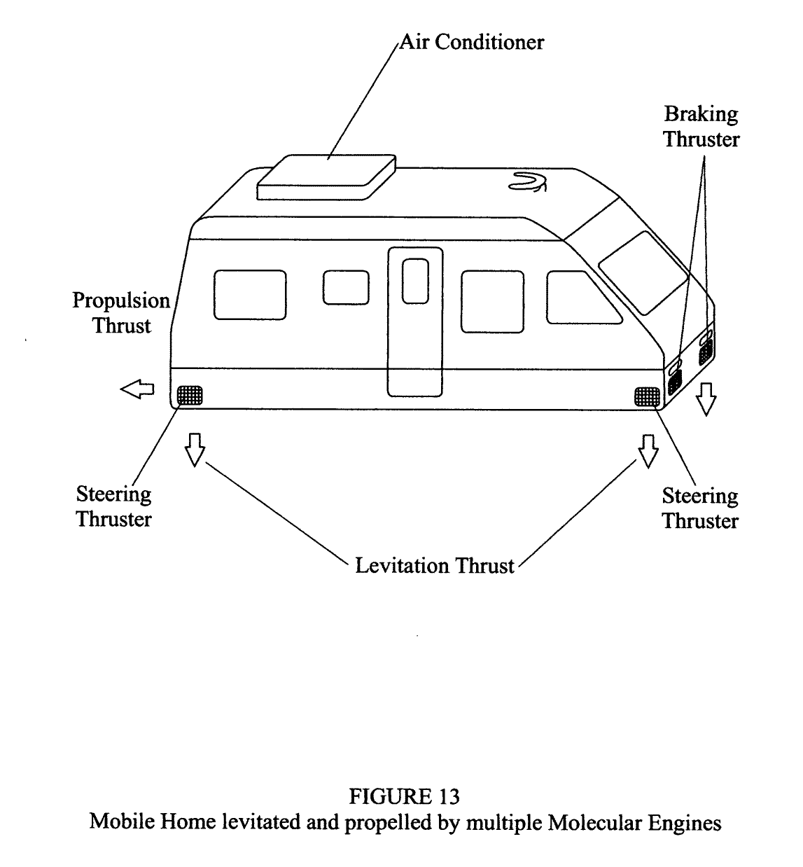

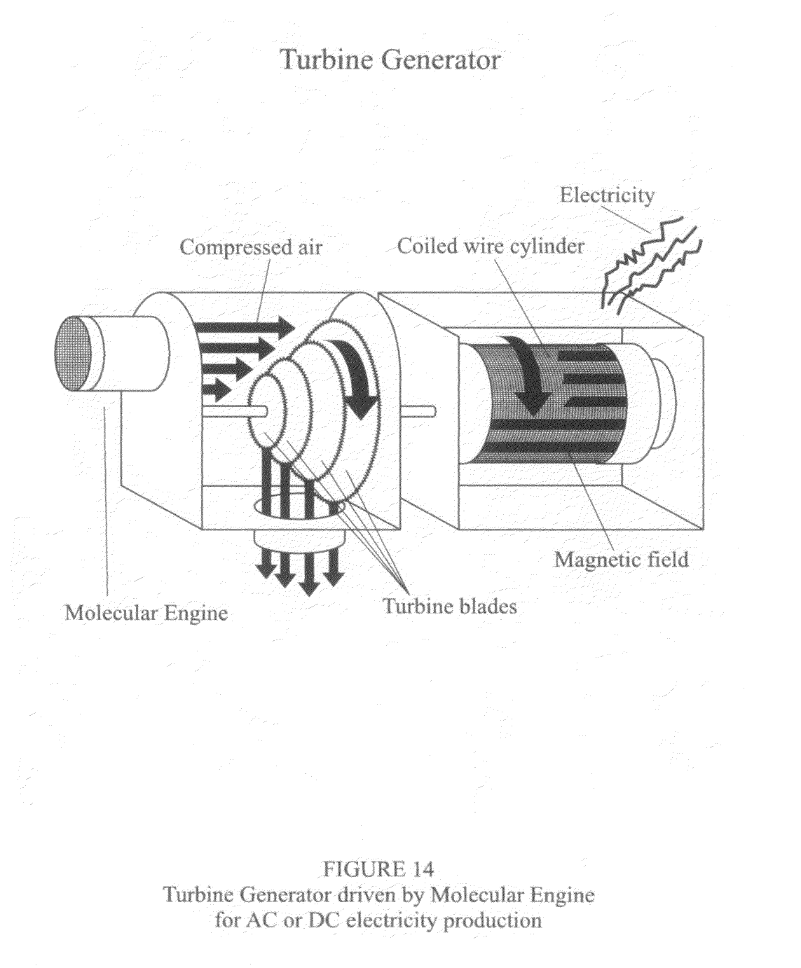

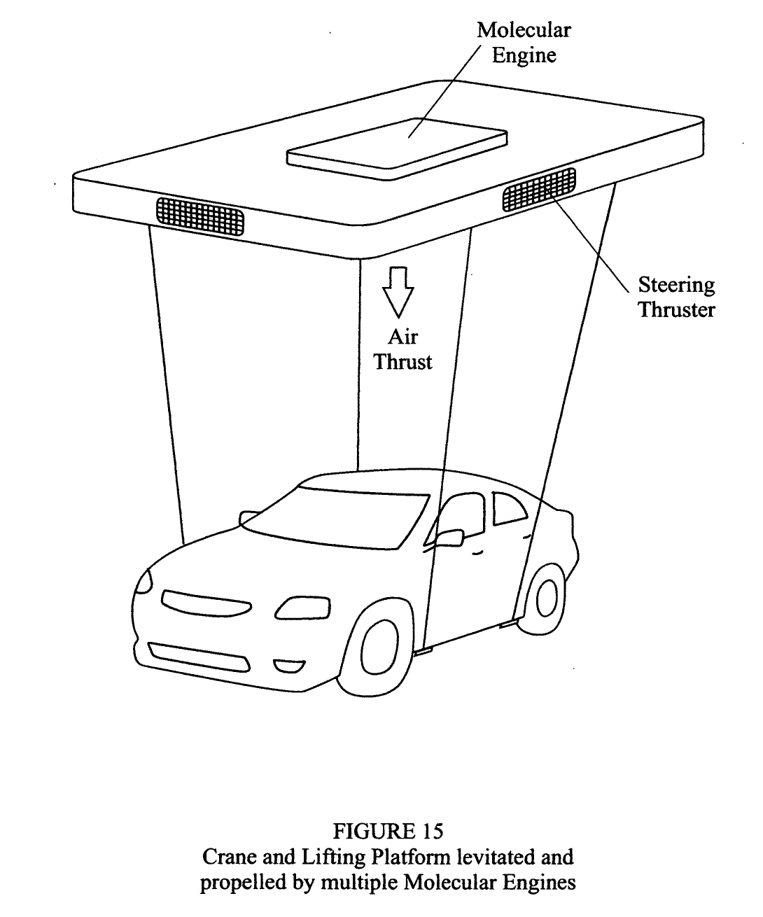

1. A through-hole drilling machine consists of multiple high repetition rate pulsed diode pumped UV lasers (only one is illustrated for clarity) [2] in FIG. 6 (such as from Coherent Inc., Santa Clara, Calif.) situated on separate linear travel guides [3] aiming at a concave focusing mirror in cylindrical length matching the radius of the substrate to be processed [4] as shown in FIG. 6, whereas the pulsed laser beams are focused on to a flat and rotating stainless steel substrate [1] (held down by vacuum from substrate holder [6,7]). Drilling by a programmed variation in the pulsing frequency and pulse width of each laser will achieve first a non-tapered through-hole of 1 to 2 microns in diameter, then a tapered top section with 8 to 10 microns at the top as illustrated in FIG. 5. Typical drilling speed of 10 mm thickness per second can be achieved, so each through-hole can be completed within one tenth of a second with the substrate thickness at less than 1 mm. The substrate is rotated at a rate that matches the drilling rate while the laser itself is translated slowly to create a tightly wound spiral pattern of through-holes on the substrate.
2. The completely drilled partition substrate [11] in FIG. 7 will then move into a vacuum chamber and held in a rotating fixture [10] for deposition of a second material (which can be by evaporation or sputtering of another metal, or electrode discharge to form carbon nanotubes [8 is the deposition source]) while it is heated by halogen lamps [9] as shown in FIG. 7. The deposition rate is precisely controlled to achieve coating of a precise thickness (in sub-nanometer precision), which will produce the through-hole with uniformed diameter with controlled precision range from a few nanometers to a few hundred nanometers.
3. The coated substrate [11] in FIG. 8A will then be diced into the specified dimensions (square, rectangular or circular) to fit into the final engine configuration as illustrated in FIG. 8A.
4. The engine exterior container is formed by two open-ended vertical halves [14] with slits cut into the interior walls [15] for positioning the partitions as shown in FIG. 8B.
5. After the partitions are inserted into one half of the exterior container the other half will be closed and several external bands/locks will hold the two halves together as shown in FIG. 8B.
6. By mechanically fitting an air intake on to the head of stack of the container [13 shows the threads for the air intake regulator [16] to screw on], the molecular engine is thus completed shown also in FIG. 8B, whereas a filter [17] is added to prevent dust particles clogging the through-holes of the partitions. [18] is electromechanical controller that adjust the opening of the air intake regulator to meter the amount of air entering into the head of the engine.
7. Other attachments can be machined or bolted to the exterior of the container for connecting the engine to its designed application.

The applications of this invention are virtually endless. Anywhere thrust, propulsion, works, rotation, electricity and gas compression are need, this invention can replace the existing methods without the requirement of any energy source, such as fossil fuel, wind, hydroelectric or direct sunlight. Not only can this invention replace every internal combustion engine used in this world, it also can substitute for any electric driven motors like pumps, compressors, cranes and conveyers. A list of applications are illustrated below, the usage of this invention is by no means limited to these areas.

By placing four of the engines, described in the calculation section above, at the four corners of a platform, the platform can levitate above ground supporting a total weight of some 900 lbs. Levitating off the ground eliminates the friction provided by the roadway as well as the need of tires. By placing an additional engine horizontally on a 360° horizontal pivot above this platform, you have a moving platform that can carry up to 4 persons or weight and travel to very high speed against just the air resistance as well as with capability to turn to any direction. With aerodynamic design, scaling up the thrust of levitation and propulsion molecular engines and by adding more of this type of molecular engines for steering and braking, this becomes a new type of vehicle, recreation vehicle, mobile home, truck, locomotive, personal mover, etc. as illustrated in FIG. 10. By incorporating existing technology of Global Positioning System (GPS) and microprocessors, one can envision a vehicle or a cargo container that can be equipped with levitating and thrust molecular engines to go from one place to another totally under programming control without piloting from a human.

By adding a jet engine (mixing fuel into compressed atmosphere and igniting the mixture) behind this molecular engine as illustrated in FIG. 11, it can produce much more propulsion thrust then just a molecular engine alone can within a unit of time. Furthermore, the molecular engine achieves the compression of air typically done by the first and second stage fans of a regular jet engine, thus these fans and its associated drive shaft and 2^{nd} stage exhaust fan performing the air compression can be eliminated to increase the thrust of the jet engine. This combination can be used to propel an airplane at a faster speed than just using molecular engine as well as at higher acceleration. In addition to propulsion, an airplane can add on its wings and fuselage the molecular engines to levitate the airplane. This configuration gives a new type of airplane that can take off and land vertically as well as the ultimate safety of floating without fuel or maintaining an aerodynamic configuration. FIG. 12 presents a conceptual configuration for this new generation of airplanes that employ molecular engines to provide levitation for vertically take off and landing (along for safety) as well as a combination with regular jet engines for thrust.

Coupling the molecular engine of this invention with a turbine to spin an electric generator will produce alternate current (AC) or direct current (DC) electricity depending on the configuration of coil windings as shown in FIG. 14. This new type of generator can be extremely compact in size and easily scaled to supply the proper amount of electricity and voltage for a single residential house, a vehicle, an apartment building, a large commercial building or a skyscraper. Since there are no moving parts in the molecular engine portion, the generator will have excellent reliability to boot, thus making blackouts a thing of the past. This type of electric generator will ultimately eliminate the need of any fossil fuel, nuclear or hydroelectric power plants, transmission grids, and the monthly electric bill for everyone.

Since atmospheric molecules are in the nanometer dimension (i.e. oxygen molecules has a diameter of around 0.3 nm and nitrogen is slightly larger), the molecular engine can be in miniature size to propel a miniature turbine and electric generator to produce DC electricity continuously. It is feasible to construct such a generator in the dimension of a single AAA battery. Consequently, the molecular engine based electric generator can be designed and constructed to replace all chemical batteries as a continuous source of electrical power of desired voltage and current without any charging required. Furthermore, the exhaust air after turning the generator can be used to cool off electronic components. One can certainly achieve true mobility and portability in cell phones, laptop computers, and virtually any electronic devices.

In military applications, not only we can have vertical take off and landing aircraft with the ultimate safety feature of unlimited flight range and survivability of large battle damages, but also an entire aircraft carrier floating on air to any location in the world (over land or sea). Furthermore, any battle weapons and equipment can be self levitated and directed to any designated place quickly including personnel. A fighting platform can be hovered indefinitely at a specific place and height to engage any enemy movement to stop insurgency, terrorist acts, drug or human smuggling. A self-positioning network of explosives can also be floated above an enemy's missiles site or above a city to form a mobile missile defense system. Many other specific applications based on this molecular engine can be designed to better the existing military applications or to create totally new capabilities for the military.

Refrigeration utilizes the phenomenon of heat absorption by a compressed gas undergoing rapid expansion. The molecular engine can accomplish compression of atmospheric gases to several atms. By allowing the compressed atmospheric gases to exit directly into a large room (i.e. expansion space), heat will be absorbed from the room and achieve space cooling effect. Therefore, this invention can be used as an air conditioner to cool a space without compressing any refrigerant and heat exchange coils. Furthermore, by using a miniature version, one can achieve cooling of a person (e.g. head and torso separately) within a garment or hat to enable the person to work and labor under hot environment. However, by expanding the compressed atmosphere gases, produced by a molecular engine, into an expansion space equipped with refrigerant recirculating system and heat exchanges, the refrigerant can then be used to cool a designated space or volume, such as a refrigerator, a freezer or walk-in cooler.

Using similar through-hole density and cross sections as presented in the calculation section above, an engine with larger dimensions, such as 12 inches (W)×12 inches (L), of each partition, can deliver a thrust of 2,116 lbs with 12-14 partitions stack together. By scaling up to even larger dimensions, the engine can be used as a crane or elevator to lift and move materials with much more degree of freedom than the exiting cranes and lifts. By properly sizing and targeted thrust power, the molecular engine from this invention can be used as a prosthetic leg and/or personal carrier to support handicapped or invalid person, as posturepedic support in terms of beds and chairs. Robotic development can also be simplified by using this invention for movement and arm/hand actions.

Another application area will be in the separation of trace organic molecules or pollutants from the atmosphere. By coating the partitions with a metal (such as Palladium) or chemical compounds, trace organic molecules or pollutants can be trapped by either adsorption or chemically reaction to the surface of the partitions. After a period of collection, the entire engine can be placed in an oven or immersed in a solvent to remove the trapped molecules. Needless to add, the engine itself is an excellent filter to provide dust free air supply to homes, clean rooms and hospital facilities.

We claim:

1. An engine, deriving its power from the translational energy of atmospheric molecules, is formed by an open ended container within which there are one or more flat and/or curved partitions in parallel with each other, and each partition has numerous through-holes with specifically designed shape aligned from partition to partition to provide a direction on the translation of the atmospheric gas molecules with higher statistical probability than the opposite direction, which is from one side of the partition toward the other side vs. traveling the reverse direction, thus resulting in more gas molecules moving toward one end of the container vs. the other. This preference in movement due to higher statistical probability results in a pressure difference between the two ends of the container, and this pressure difference can then be used for propelling the container, for rotating a turbine to generate electricity, for performing works, for compressing gases and/or for performing rapid expansion to achieve a cooling effect. This engine shall be designated as a molecular engine as referred to in the subsequent claims.

2. The through-holes with specifically designed shape as described in claim 1 can be in a funnel shape, i.e. one end of the opening is large and gradually taper down to a small diameter hole of a stem tube. The type of taper can be cylindrical or flat sided, and the stem portion can be of any length.

3. The diameters at the top of the tapered through-hole and the smaller bottom end holes of the stem tube as described in claim 2 shall be in the range of few times of the size of nitrogen molecule (which is around 0.3 nanometer) to several ten times of the mean free-path length of atmospheric molecules at sea level (which is around 60 nanometers); while the length of the through-holes (i.e. from the top of the taper hole to the bottom end-hole of the stem tube) shall be in the range from less than the mean free-path of atmospheric molecules at sea level to several hundred times of the mean free-path length.

4. The partition, which forms the support structure of the through-holes as described in claim 1, can have thickness range from identical to the through-hole length to several hundred times of the through-hole length.

5. The partition as described in claim 1 can have a plate with a large number of non-tapered through-holes (channels), i.e. uniformed hole diameter from both ends, placed on top of it or as an integral part of the partition, and these channels shall overlap the large end of the specially shaped through-holes on the partition to guide the gas molecules into these specially shaped through-holes.

6. The partition as described in claim 1 can also have a plate with a large number of non-tapered through-holes (channels) placed beneath it or as an integral part of the partition, and those channels shall overlap the small end of the specially shaped through-holes on the partition to guide the gas molecules into next partition as well as reducing the angles of incidence into the small-end of the specially designed through-holes of the partition for the molecules traveling from the smaller end-hole side to the larger diameter hole side.

7. To fabricate a partition and its associated through-holes to comply with the description in claim 1, a variety of through-holes forming and/or drilling methods can be utilized, however, due to technical limitations, hole dimensions may have to be modified by thin film deposition and/or nano-particle adherence processes to create the dimension to achieve the effect of producing a higher statistical probability in transitional direction for atmospheric molecules through a partition than the reverse.

8. The method described in claim 7 can be as follows:
(1) One or more pulsed lasers are focused to drill a specified number of taper through-holes or viases on a substrate.
(2) The thickness of the substrate is reduced from the opposite side of the taper through-hole or viases either on entire surface area or locally at site opposite to the holes/viases by laser drilling (straight side wall) and/or photolithographic (resist coating, exposure and developing)/etching processes to expose the holes/viases to the right diameter of the stem end.
(3) The finished substrate will then be cut into proper dimensions to fit into an open-ended container (cylindrical, rectangular or square) to form the molecular engine.

9. The method described in claim 7 can also be as follows:
(1) One or more pulsed lasers are focused to drill a specified number of taper through-holes or viases on a substrate.
(2) The thickness of the substrate is reduced from the opposite side of the taper through-hole or viases either on entire surface area or locally at site opposite to the holes/viases by laser drilling (straight side wall) and/or photolithographic (resist coating, exposure and developing)/etching processes to expose the holes/viases to the right diameter of the stem end.
(3) The substrate then undergoes deposition of layers (thickness per layer in the order of one or more nanometers) of materials (which can be metal, organic polymer, inorganic compounds or nano-material like carbon nanotube) to form the taper through-holes with desired diameters of openings (top and bottom end-hole).
(4) The finished substrate will then be cut into proper dimensions to fit into an open-ended container (cylindrical, rectangular or square) to form the molecular engine.

10. The method described in claim 7 can also be as follows:
(1) Circular substrate can be placed on to a rotating holder, which will be spin at a specific speed to match the hole drilling rate of the pulsed laser.
(2) One or more pulsed lasers and each placed on a separate linear translational track are focused to drill a specified number of tapered through-holes or viases (with the diameter of top of the hole virtually touching each other) in a spiral pattern from the edge toward the center of the circular substrate.
(3) The thickness of the substrate is reduced from the opposite side of the taper through-hole or viases either on entire surface area or locally at site opposite to the holes/viases by laser drilling (straight side wall) and/or photolithographic (resist coating, exposure and developing)/etching processes to expose the holes/viases to the right diameter of the stem end.
(4) The substrate then undergoes deposition of layers (thickness per layer in the order of one or more nanometers) of materials (which can be metal, organic polymer, inorganic compounds or nano-material like carbon nanotube) to form the tapered through-holes with desired diameters of openings (top and bottom of the through-hole).
(5) The finished substrate will then be cut into proper dimensions to fit into an open-ended container (cylindrical, rectangular or square) to form the molecular engine.

11. The method described in claim 7 can be also as follows:
(1) An injection mold (father and mother) is fabricated using a combination of photolithographic (resist coating, exposure and developing)/etching processes and an electron beam (EB) machining or ion beam machining technique to create densely patterned needles and matching tapered pin holes of a few microns in diameter.
(2) A substrate material such as polycarbonate or other plastics is injection molded to form a partition with densely patterned through-holes.
(3) The substrate then undergoes deposition of layers (thickness per layer in the order of one or more nanometers) of materials (which can be metal, organic polymer, inorganic compounds or nano-material like carbon nanotube) to form the tapered through-holes with desired diameters of openings (top and bottom of the through-hole).
(4) The finished substrate will then be cut into proper dimensions to fit into an open-ended container (cylindrical, rectangular or square) to form the molecular engine.

12. The method described in claim 7 can be also as follows:
(1) Nanoparticles of metal (such as nickel) is coated on the processing side of a substrate (of glass, silicon, ceramic or metal) by chemical vapor deposition, sputtering, electric discharge or plasma enhanced chemical vapor deposition;
(2) Also by chemical vapor deposition, plasma enhanced chemical vapor deposition or electrical discharge, an array of carbon or inorganic nanotubes (diameter range in the tens of nanometers) bounded to one another is grown on the side having nanoparticle coating;
(3) This array of nanotubes will have their opened ends away from the substrate while the other end is tapered down to a small diameter to be sealed by the nanoparticle(s) which was coated over the substrate during the first step.
(4) Micron size holes will then be etched (utilizing photolithographic/etching processes) on the substrate from the opposite side of the nanoparticle coated side until nanotubes are exposed;
(5) Then, the nanoparticle(s) that seal one end of all the nanotubes are etched away to form an array of tapered nanotubes with two open ends while one opening is larger than the other.
(6) Again, the finished substrate is cut to into proper dimensions to fit into an open-ended container to form the molecular engine.

13. The method described in claim 7 can also be as follows:
(1) An array of thick walled inorganic nanotubes bounded to one another is grown on one side of a substrate by electric discharge, chemical vapor deposition or plasma enhanced chemical vapor deposition;
(2) Micron size holes will then be etched (utilizing photolithographic/etching processes) from the opposite side of the substrate until nanotubes are exposed;
(3) Heat treating the end of the nanotubes away from the substrate to shrink the nanotubes'diameter at this end, thus creating a funnel shaped tube with a larger opening at the substrate end.
(4) Again, the finished substrate is cut to into proper dimensions to fit into an open-ended container to form the molecular engine.

14. A container as described in claim 1 can have a control (mechanical or electromechanical) on the opening at the head of the stack of partitions to meter the amount of air entering into this end, thus controlling the amount of pressure difference as well as thrust that can be achieved by the molecular engine. This control also serves as the ultimate on-off switch of the engine. This control may also have filter(s) to prevent dust particles entering into the container.

15 . A container as described in claim 14 can further be placed in front of a jet engine to provide compressed air to mix with fuel vapor for ignition to produce additional propulsion thrust than just a molecular engine can. This usage may also eliminate the typical air compression intake turbine blades and afterburner turbine blades (which is used to rotate the air intake turbine blades), thus providing added thrust for the jet engine.

16. The utilization of one or more containers as described in claim 14 to provide the thrust to propel a vehicle (including all types of cars, trucks, airplanes, ships, trains, buses, motorcycles, recreational vehicles, mobile homes, etc.), a platform or any object.

17. The utilization of one or more containers as described in claim 15 in conjunction with a fossil fuel supply to deliver additional thrust to increase acceleration and speed of a vehicle, an airplane, a platform or any object.

18. The utilization of one or more containers as described in claim 14 to provide the levitational thrust for a vehicle, platform and/or any object to enable it to be moved without surface friction. This levitational thrust can be controlled by height and horizontal leveling sensors (i.e. adjusting the amount of air intake of individual containers as described in claim 14 to change height and/or leveling of the vehicle, platform and/or object).

19. The utilization of one or more molecular engines as described in claim 14 to provide the levitational thrust for an airplane to enable it take off and land vertically as well as in the case of propulsion jet engine failure or damage to the airframe to achieve safe landing.

20. The utilization of one or more containers as described in claim 14 pointing at different directions to provide steering and braking of a levitating vehicle, platform and/or object.

21. The utilization of one or more containers as described in claim 14 to rotate a turbine to turn an alternate current (AC) and/or direct current (DC) electric generator to produce electricity for all electric power consumption applications.

22. The utilization of a miniaturized version of a container or containers as described in claim 14 to rotate a miniaturized DC electric generator or generators to provide continuous and constant DC power source in replacement of a chemical battery or battery pack.

23. The utilization of one or more containers as described in claim 14 as a compressor for gases (such as oxygen, nature gas, propane, etc.) after their separation process to deliver it to its applications or storage tanks.

24. The utilization of one or more containers as described in claim 14 to compress air and then allow rapid expansion to directly cool a designated space, such as integrated with garment to cool human body/head, or to serve as a cooling source for a recirculating refrigerant to achieve refrigeration of a space like a refrigerator, freezer and/or room.

25. The utilization of one or more containers as described in claim 14 to levitate, propel or control descent of a space vehicle exploring Mars or any planets and/or their moons that have an atmosphere.

26. The utilization of one or more containers as described in claim 14 for prosthetic limb/support and/or for levitating and propelling purposes to enhance the mobility of handicapped or invalid persons, animals or robots.

27. The utilization of one or more containers as described in claim 14 for lifting any object or machinery as a crane and/or elevator.

28. The utilization of one or more containers as described in claim 1 for shock absorption application such as for buildings, elevated roadways and bridges to reduce and/or eliminate earthquake damage as well as providing temporary support during any repair period.

29. The utilization of one or more containers as described in claim 15 to propel and levitate a manned or unmanned weapon system, such as bombs, missiles, fighter airplanes, armored fighting vehicles, explosive projectiles, fighting ships, aircraft carriers and floating network of explosive cells for missile defense. The unmanned explosives can become a distributed stationary minefield in the sky and/or sequential penetrators of cave or underground bunkers.

30. The engine described in claim 14 can be further modified by coating its partitions with an adsorbing metal or reactive chemical compounds, which will trap any organic molecules (such as carbon tetrachloride, methane, etc.) or pollutant molecules (like nitrogen oxides, sulfur oxides) by adsorption mechanism or chemical reaction, to serve as air scrubber and/or air pollutant removing device.

31. The utilization of one or more containers as described in claim 14 as air filtration system to eliminate dust and bacterial particles in air for home, hospital and clean-room applications.

32. The utilization of one or more containers as described in claim 14 in miniaturized versions to levitate and propel a miniature platform housing surveillance equipment, such as pin-hole camera, microphone and transmitter/receiving devices, to conduct covert surveillance in law enforcement, border patrol and/or military applications.

33. The method described in claim 7 can also be as follows:
(1) A master stamper is fabricated using a combination of photolithographic (resist coating, exposure and developing)/etching processes and an electron beam (EB) machining and/or ion beam machining technique to create a densely patterned needles in a uniformed conical shape (with tapering angle ranging from a few degrees to 45-degree) and the diameter of each needle base can range from 0.5 micron to a few microns.
(2) A substrate preform in material such as polycarbonate or other plastics is inserted into the injection molding machine and heated before molding with the master stamper to form a densely patterned conical pits on one of the substrate surface.
(3) The pitted substrate then undergoes photolithographic and etching processes to create a through-hole centered in each pit with diameter of 0.2 micron or smaller.
(4) After the removal of resist material, the resulting substrate will have a densely patterned through-holes, and all are in funnel shape with designed dimensions.
